(19) United States
(12) Patent Application Publication
(10) Pub. No.: US 2006/0163750 A1
(43) Pub. Date: Jul. 27, 2006

(54) Semiconductor device and method for producing the same

(75) Inventor: Satoshi Kaneko, Kanagawa (JP)

Correspondence Address: YOUNG & THOMPSON, 745 SOUTH 23RD STREET, 2ND FLOOR, ARLINGTON, VA, 22202, US

(73) Assignee: NEC COMPOUND SEMICONDUCTOR DEVICES, LTD., KANAGAWA (JP)

(21) Appl. No.: 11/336,853

(22) Filed: Jan. 23, 2006

(30) Foreign Application Priority Data
Jan. 26, 2005 (JP) 2005-018556
Dec. 27, 2005 (JP) 2005-375113

(51) Int. Cl. H01L 23/48; H05K 3/30

(52) U.S. Cl. 257/778; 29/832; 257/777; 29/854

(57) ABSTRACT

A semiconductor device provided with a stabilized hollow structure. A semiconductor device 1 having a semiconductor chip 3 flip chip-mounted on a substrate 2 includes a plate-shaped member 4 arranged on a surface of the semiconductor chip 3 opposite to its flip chipped surface. The plate-shaped member is protruded more outwards than the lateral end faces of the semiconductor chip. A resin sheet 5 overlies a surface of the plate-shaped member opposite to its surface bonded to the semiconductor chip 3, and is bent onto the substrate 2 over an edge part of plate-shaped member 4, without being contacted with the semiconductor chip 3, until an edge part of the resin sheet gets to the substrate and is bonded there to the substrate.

### FIELD OF THE INVENTION

This invention relates to a semiconductor device and a method for producing the same. More particularly, the present invention relates to a semiconductor device of a hollow structure in which the surface of a semiconductor chip for high frequencies is contacted with an air layer.

### BACKGROUND OF THE INVENTION

Recently, there is a requirement for increasing the transmission speed, in keeping with development of the mobile communication techniques. More specifically, there is a requirement for increasing the capacity of data entailed by realization of mobile communication including transmission of detailed moving pictures. However, the frequency band currently usable for mobile communication is about to be used up and hence it is being contemplated to raise the usable frequency. It is therefore necessary for the semiconductor device, used for mobile communication, to be able to cope with the higher frequency. For raising the usable frequency, it is necessary to use a structure which diminishes the dielectric constant of the dielectric material and an internal interconnection which is of a shorter length. Thus, there is a demand for a semiconductor device having a hollow structure and a flip chip configuration.

As a conventional semiconductor device having a hollow structure and a flip chip configuration (surface acoustic wave device), there is known a surface acoustic wave device 10 which includes a substrate for mounting 11, a surface acoustic wave element 13, mounted on this substrate for mounting 11, and a resin film 15 for protecting this substrate for mounting 11, in which there is delimited a spacing 16 between a surface 11a of the substrate for mounting 11 and a surface 13a of the surface acoustic wave element 13, facing the surface 11a of the substrate for mounting. The resin film 15 includes a dome-shaped part 15a surrounding the surface acoustic wave element 13 and a rim part 15b arranged around the surface acoustic wave element 13. The resin film 15 is arranged on the substrate for mounting 11 so that the dome-shaped part 15a surrounds the surface acoustic wave element 13. The rim part 15b is bonded to the substrate for mounting 11 in a portion thereof surrounding the surface acoustic wave element 13 (see FIG. 3 and Patent Publication 1). The spacing 16 is delimited between the surface 13a of the surface acoustic wave element 13 and the surface 11a of the substrate for mounting 11 in order to prevent the operation of the surface acoustic wave element 13 from being affected by collision of the surface 13a of the surface acoustic wave element 13 against other objects.

[Patent Document 1]

Japanese Patent Kokai Publication No. JP-P2002-330049A

### SUMMARY OF THE DISCLOSURE

The method for producing a surface acoustic wave device, disclosed in the Patent Publication 1, includes a step of sucking a resin film 15, with use of a jig having a suction means for sucking a gas on an inner wall section of the dome-shaped part 15a and within a hollow part 17 surrounded by the inner wall section, for deforming the shape of the resin film 15 so that part of the resin film will present a dome shape, and for holding the resin film 15, a step of mounting the resin film 15, held by the jig, for surrounding the surface acoustic wave element 13, and a step of heating the resin film 15, as the resin film 15 is pressed onto the substrate 11 for mounting in the rim part of the surface acoustic wave element 13, to render the resin film 15 flexible, and subsequently curing the resin film 15 to bond the resin film 15 to the substrate 11 for mounting. With this method, there is a risk that, due to slight variations in the manufacture conditions, uncured portions of the resin film 15 get to the face-down connecting surface of the surface acoustic wave element 13 to produce resin bleeding in which the low molecular weight resin within the bulk of the resin film 15 flows along the lateral surface of the surface acoustic wave element 13 to contaminate the operating portions on the surface of the surface acoustic wave element 13. In case the operating portions on the surface of the surface acoustic wave element 13 are contaminated with the resin, the dielectric constant becomes variable to deteriorate high frequency characteristics. Hence, if this method is used, fabrication of the hollow structure is significantly destabilized.

It is an object of the present invention to be able to form a stabilized hollow structure.

In one aspect, the present invention provides a semiconductor device having a semiconductor chip flip chip-mounted on a substrate, in which the semiconductor device comprises a plate-shaped member arranged on a surface of the semiconductor chip opposite to its flip chipped surface, and the plate-shaped member protrudes outwards beyond the lateral end faces of the semiconductor chip, and a resin sheet covering up a surface of the plate-shaped member opposite to its surface facing the semiconductor chip, with an edge part of the resin sheet getting to the substrate and being bonded there to the substrate.

In the semiconductor device of the present invention, the resin sheet preferably is bent onto the substrate, from the edge part of the plate-shaped member, without being contacted with the semiconductor chip.

In the semiconductor device of the present invention, the length by which the plate-shaped member is protruded from the lateral end faces of the semiconductor chip preferably is not less than 180 μm.

In the semiconductor device of the present invention, the plate-shaped member preferably is of a dual layer structure of a heat-resistant resin layer and an adhesive layer.

In a second aspect, the present invention provides a method for producing a semiconductor device having a semiconductor chip flip chip-mounted on a substrate, in which the method comprises a step of arranging a plate-shaped member on a surface of the semiconductor chip opposite to its flip chipped surface, so that the plate-shaped member protrudes outwards beyond the lateral end faces of the semiconductor chip, and a step of covering up the plate-shaped member with an uncured resin sheet, bonding the edge part of the resin sheet to said substrate and curing the resin sheet.

In the method for the preparation of a semiconductor device, the bonding of the resin is conducted so that the resin sheet and the semiconductor chip are not in contact with each other in the step of bonding the edge part of the resin sheet to the substrate.

The meritorious effects of the present invention are summarized as follows.

According to the present invention, the plate-shaped member, more specifically, the lateral end faces thereof protruded from the lateral end faces of the semiconductor chip, operate to prevent the resin sheet from being moved onto the lateral end faces of the semiconductor chip, and hence a stabilized hollow structure in which the resin sheet and the semiconductor chip are not contacted with each other may be provided to prevent resin bleeding from occurring.

### BRIEF DESCRIPTION OF THE DRAWINGS

FIG. 1 is a schematic cross-sectional view showing the configuration of a semiconductor device according to a first embodiment of the present invention.

FIGS. 2A, 2B and 2C are schematic cross-sectional views showing a method for producing a semiconductor device according to the first embodiment of the present invention.

FIG. 3 is a schematic cross-sectional view showing the configuration of a conventional semiconductor device (surface acoustic wave device).

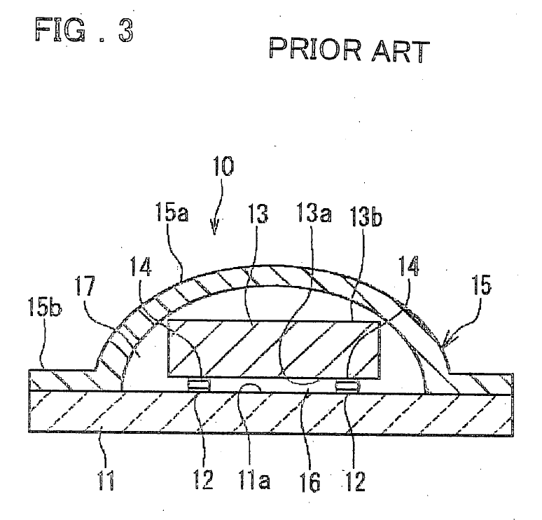

### PREFERRED EMBODIMENTS OF THE INVENTION

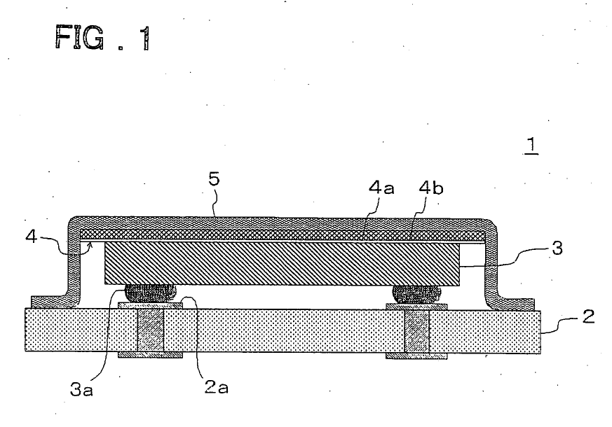

Referring to the drawings, a semiconductor device according to a first embodiment of the present invention will be explained in detail. FIG. 1 depicts a schematic cross-sectional view showing the configuration of a semiconductor device 1 according to the first embodiment of the present invention.

The semiconductor device 1 is a device having a hollow spacing and a flip chip structure, and may be used for electronic equipment for high frequency application, such as mobile communication devices. The semiconductor device 1 includes a substrate 2, a semiconductor chip 3, a plate-shaped member 4 and a resin sheet 5.

The substrate 2 is a plate-shaped member of an insulating material, such as glass, resin or ceramics, on the surface or in the interior of which is formed an electrical interconnection, not shown. The substrate 2 has electrodes 2a, such as Au electrodes, on its surface facing the semiconductor chip 3. The electrodes 2a are provided in register with bumps 3a provided to the semiconductor chip 3.

The semiconductor chip 3 is e.g. a chip for high-frequency application, and is mounted to the substrate 2 by face-down bonding. The semiconductor chip 3 includes the bumps 3a, such as Au bumps, on its surface facing the substrate 2. These bumps 3a are arranged in register with the electrodes 2a of the substrate 2. The bumps are bonded to the electrodes 2a by a flip chip technique (i.e., flip chip bonding). The semiconductor chip 3 is electrically connected to the substrate 2 via bumps 3a and electrodes 2a.

The plate-shaped member 4 is a plate-shaped member of a double layer structure, comprised of a layer of a heat-resistant resin 4a and a layer of an adhesive 4b, and is bonded via adhesive 4b to the surface of the semiconductor chip 3 opposite to its surface carrying the bumps 3a. The plate-shaped member 4 is protruded outwards beyond the lateral end faces of the semiconductor chip 3. The length by which the plate-shaped member 4 is protruded from the lateral end faces of the semiconductor chip 3 is preferably not less than 70 μm and more preferably not less than 180 μm and not larger than 190 μm. It is preferably the surface of the plate-shaped member 4 bonded to the semiconductor chip 3 that is coated with the adhesive 4b. The outer size and shape of the plate-shaped member 4 are preferably slightly larger than those of the semiconductor chip 3. The detailed size and shape of the plate-shaped member 4 are determined so that the resin sheet 5 will not contact with the lateral end faces of the semiconductor chip 3 at the time of encapsulation with resin. The plate-shaped member 4 is of such a thickness or a material type that it is not bent at the time of resin encapsulation, or that, if the plate-shaped member is bent to some extent, the plate-shaped member, so bent, is still effective to prevent the resin sheet 5 from contacting with the lateral end faces of the semiconductor chip 3. With the plate-shaped member thus exhibiting the bending strength, the low molecular resin in the bulk of the resin sheet 5 is not allowed to flow along the lateral end faces of the semiconductor chip 3 to prevent the resin bleeding from occurrence.

The resin sheet 5 is a sheet-shaped member of resin which covers up the surface of the plate-shaped member 4 opposite to its surface bonded to the semiconductor chip 3, such as to allow for encapsulation of the semiconductor chip 3 and the plate-shaped member 4. The resin sheet 5 is contacted with the surface of the plate-shaped member 4, opposite to its surface bonded to the semiconductor chip 3, and is bent down from the edges of the plate-shaped member 4 onto the substrate 2, without having contact with the semiconductor chip 3, until the edges of the resin sheet 5 get to the substrate 2 and are there bonded to the substrate. In a hollow space between the resin sheet 5 and the substrate 2 is charged a gas, such as air, a nitrogen gas or an inert gas. As a material for the resin sheet 5, a thermosetting resin, such as, for example, epoxy resin, may be used. The thickness of the resin sheet 5 is set so that, even if a gas pressure differential is produced in a greater or lesser degree between the inside and the outside of the sheet, the resin sheet 5 will not come to contact with the lateral end faces of the semiconductor chip 3.

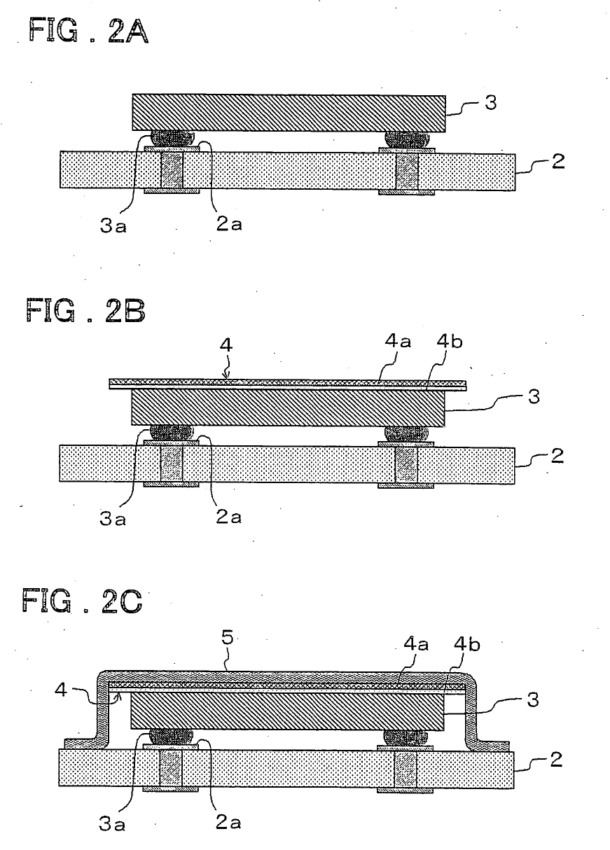

Referring to the drawings, a method for producing a semiconductor device according to the first embodiment of the present invention will be explained in detail. FIGS. 2A to 2C schematically show a method for the preparation of the semiconductor device according to the first embodiment of the present invention, step-by-step.

Initially, the semiconductor chip 3 is flip chip-mounted on the substrate 2 (see FIG. 2A). Specifically, the semiconductor chip 3 is set on the substrate 2, so that the bumps 3a and the electrodes 2a will be in register with each other. The semiconductor chip 3 is pressured against the substrate 2 under a predetermined pressure. Simultaneously, the semiconductor chip 3 and the substrate 2 are heated at a predetermined heating temperature to carry out thermal press bonding for a predetermined time. By so doing, the semiconductor chip 3 is bonded to the substrate 2, while the bumps 3a and the electrodes 2a are electrically connected to each other.

The plate-shaped member 4 is then bonded to the surface of the semiconductor chip 3 as flip chip-mounted to the substrate 2 (the surface of the semiconductor chip 3 not carrying the bumps 3a), as shown in FIG. 2B. Specifically, the plate-shaped member 4, on the bonding surface of which is coated the adhesive 4b, is placed so that the edges of the plate-shaped member will protrude beyond the lateral end faces of the semiconductor chip 3, for bonding the plate-shaped member to the surface of the semiconductor chip 3.

Finally, the semiconductor chip 3 and the plate-shaped member 4 on the substrate 2 are encapsulated with a resin sheet 5 (see FIG. 2C). Specifically, the resin sheet 5 in an uncured state is placed over the surface of the substrate 2 to cover the plate-shaped member 4, so that the edge part of the resin sheet 5 will reach the substrate 2. The resulting assembly is heated in a constant temperature vessel at a preset temperature (such as 170° C.) for a preset period of time (such as one hour) for curing the resin sheet 5.

With the present second embodiment, the resin sheet 5 may be prevented from being moved (flown) onto the lateral end faces of the semiconductor chip 3, by the plate-shaped member 4, more precisely by the edge part of the plate-shaped member 4 protruded from the lateral end faces of the semiconductor chip 3, thus providing a stabilized hollow structure in which the resin sheet 5 is not in contact with the semiconductor chip 3.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device having a semiconductor chip flip chip-mounted on a substrate, comprising
a plate-shaped member arranged on a surface of said semiconductor chip opposite to a flip chipped surface thereof, said plate-shaped member protruding outwards beyond lateral end faces of said semiconductor chip; and
a resin sheet covering up a surface of said plate-shaped member opposite to the surface thereof facing said semiconductor chip, with an edge part of said resin sheet getting to said substrate and being bonded there to said substrate.

2. The semiconductor device as defined in claim 1 wherein said resin sheet is bent onto said substrate, over the edges of said plate-shaped member, without being contacted with said semiconductor chip.

3. The semiconductor device as defined in claim 1 wherein said plate-shaped member protrudes beyond the lateral end faces of said semiconductor chip by a length of at least 180 μm.

4. The semiconductor device as defined in claim 1 wherein said plate-shaped member has a dual layer structure formed of a heat-resistant resin layer and an adhesive layer.

5. The semiconductor device as defined in claim 1 wherein there is a spacing between said resin sheet and said substrate excepting said semiconductor chip and the plate-shaped member.

6. A method for producing a semiconductor device having a semiconductor chip flip chip-mounted on a substrate, said method comprising the steps of;
arranging a plate-shaped member on a surface of said semiconductor chip opposite to a flip chip-bonded surface thereof, so that said plate-shaped member protrudes outwards beyond lateral end faces of said semiconductor chip;
covering up said plate-shaped member with an uncured resin sheet; and
bonding the edge part of said resin sheet to said substrate and curing the resin sheet.

7. The method for the preparation of a semiconductor device as defined in claim 6 wherein, in said step of bonding the edge part of said resin sheet to said substrate, said resin sheet and the semiconductor chip are not contacted with each other.
